(19) United States
(12) Patent Application Publication
(10) Pub. No.: US 2023/0402278 A1
(43) Pub. Date: Dec. 14, 2023

(54) SEMICONDUCTOR DEVICES AND METHODS OF FORMING THE SAME

(71) Applicant: Taiwan Semiconductor Manufacturing Company, Ltd., Hsinchu (TW)

(72) Inventors: Yan-Ming Tsai, Miaoli County (TW); Wei-Yip Loh, Hsinchu City (TW); Harry CHIEN, Chandler, AZ (US); Chih-Shiun Chou, Hsinchu City (TW); Hong-Mao Lee, Hsinchu City (TW); Chih-Wei Chang, Hsin-Chu (TW); Ming-Hsing Tsai, Hsinchu (TW)

(73) Assignee: Taiwan Semiconductor Manufacturing Company, Ltd., Hsinchu (TW)

(21) Appl. No.: 17/838,253

(22) Filed: Jun. 12, 2022

(51) Int. Cl. H01L 21/02

(52) U.S. Cl. CPC H01L 21/02123; H01L 21/02293; H01L 21/02381

(57) ABSTRACT

A method of forming a semiconductor device includes following operations. A substrate is provided with a gate stack thereon, an epitaxial layer therein, and a dielectric layer aside the gate stack and over the epitaxial layer. An opening is formed through the dielectric layer, and the opening exposes the epitaxial layer. A metal silicon-germanide layer is formed on the epitaxial layer, wherein the metal silicon-germanide layer includes a metal having a melting point of about 1700° C. or higher. A connector is formed over the metal silicon-germanide layer in the opening.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of manufacturing ICs and, for these advances to be realized, similar developments in IC manufacturing are needed. For example, a three dimensional transistor, such as a fin-type field-effect transistor (FinFET), has been introduced to replace a planar transistor. Although existing FinFET devices and methods of forming FinFET devices have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1 to FIG. 19 are cross-sectional views of a method of forming a semiconductor device in accordance with some embodiments of the present disclosure.

FIG. 20 to FIG. 21 are cross-sectional views of semiconductor devices in accordance with some embodiments of the present disclosure.

FIG. 22 illustrates a method of forming a semiconductor device in accordance with some embodiments of the present disclosure.

FIG. 23 illustrates a method of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on” “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

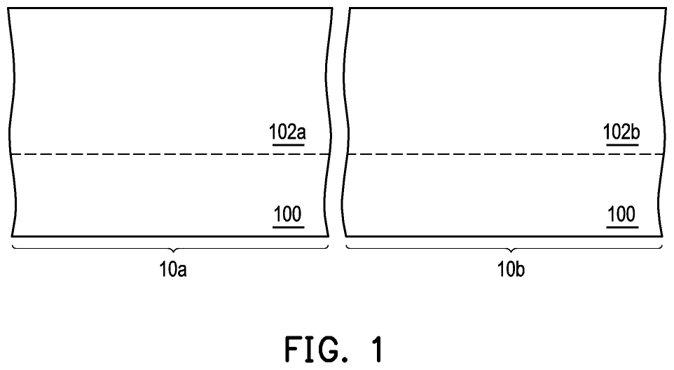

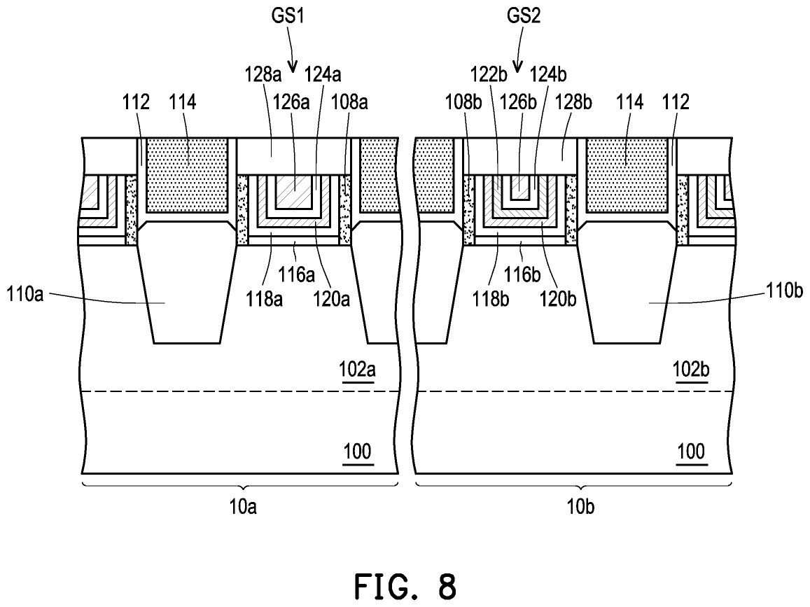

FIG. 1 to FIG. 19 are cross-sectional views of a method of forming a semiconductor device in accordance with some embodiments.

Referring to FIG. 1, a substrate 100 is provided. In some embodiments, the substrate 100 has at least one first fin 102a in a first region 10a and at least one second fin 102b in a second region 10b. The first and second fins 102a and 102b may be arranged in parallel and extend in a direction. In some embodiments, the substrate 100 includes a silicon substrate, a silicon-on-insulator (SOI) substrate, a silicon germanium substrate, or a suitable semiconductor substrate. Other semiconductor materials including group III, group IV, and group V elements may also be used. In some embodiments, the first region 10a and the second region 10b are adjacent to each other. In some embodiments, the first region 10a is an N-type device region configured for an N-type FinFET device, and the second region 10b is a P-type device region configured for a P-type FinFET device. Depending on the requirements of design, the substrate 100 may have doped regions therein. The doped regions may be configured for an N-type FinFET device or a P-type FinFET device.

The first and second fins 102a and 102b may protrude upwardly from the surface of the substrate 100. In some embodiments, the first and second fins 102a and 102b have inclined sidewalls. In other embodiments, at least one of the first and second fins 102a and 102b have substantially vertical sidewalls. In some embodiments, the substrate 100 has an isolation layer (not shown) formed thereon. Specifically, the isolation layer covers the lower portions while exposes the upper portions of the first and second fins 102a and 102b. In some embodiments, the isolation layer is a shallow trench isolation (STI) structure.

In some embodiments, the first and second fins 102a and 102b and the substrate 100 are made of the same material, such as silicon. In other embodiments, one of the first and second fins 102a and 102b includes a material different from that of the substrate 100. For example, the second fin 102b includes silicon germanium and the substrate 100 includes silicon.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

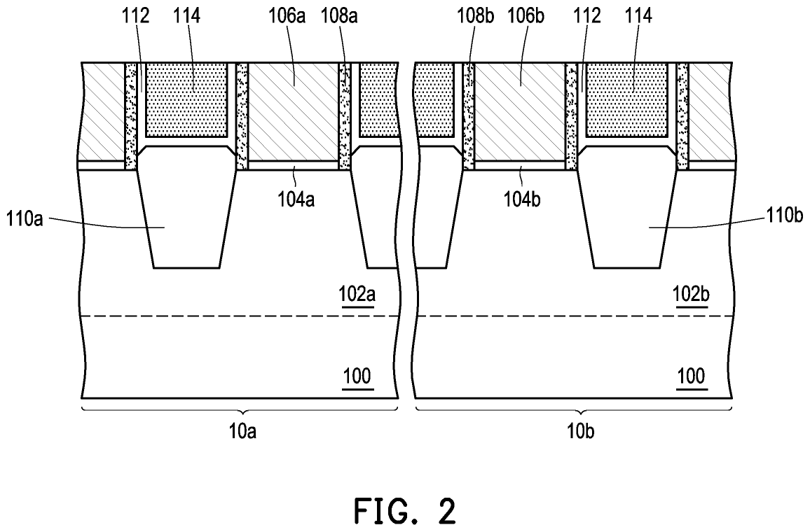

Referring to FIG. 2, a first dummy gate strip 106a is formed across the first fin 102a, first spacers 108a are formed on sidewalls of the first dummy gate strip 106a, and first epitaxial layers 110a are formed in the first fin 102a beside the first dummy gate strip 106a. Similarly, a second dummy gate strip 106b is formed across the second fin 102b, second spacers 108b are formed on sidewalls of the second dummy gate strip 106b, and second epitaxial layers 110b are formed in the second fin 102b beside the second dummy gate strip 106b.

In some embodiments, the first and second fins 102a and 102b extend in a first direction, and the first and second dummy gate strips 106a and 106b extend in a second direction different from (e.g., perpendicular to) the first direction. In some embodiments, the first and second dummy gate strips 106a and 106b include a silicon-containing material, such as polysilicon, amorphous silicon or a combination thereof. In some embodiments, a first interfacial layer 104a is formed between the first dummy gate strip 106a and the first fin 102, a second interfacial layer 104b is formed between the second dummy gate strip 106b and the second fin 102b. In some embodiments, the first and second interfacial layers 104a and 104b include silicon oxide, silicon oxynitride or a combination thereof.

In some embodiments, the first and second spacers 108a and 108b have a dielectric constant less than about 10, less than about 7 or even less than about 5. In some embodiments, the first and second spacers 108a and 108b include a nitrogen-containing dielectric material, a carbon-containing dielectric material or both. In some embodiments, the spacers 108a include SiN, SiCN, SiOCN, SiC, SiOC, SiON, the like, or a combination thereof.

In some embodiments, the first epitaxial layers 110a include silicon carbon (SiC), silicon phosphate (SiP), SiCP or a SiC/SiP multi-layer structure for an N-type FinFET device. In some embodiments, the first epitaxial layers 110a may be optionally implanted with an N-type dopant as needed. The N-type dopant may include P, As, Sb or the like. In some embodiments, the second epitaxial layers 110b include silicon germanium (SiGe) for a P-type FinFET device. In some embodiments, the second epitaxial layers 110b may be optionally implanted with a P-type dopant as needed. The P-type dopant may include B, Ga or the like. In some embodiments, the first epitaxial layers 110a and second epitaxial layers 110b are formed by in-situ heavily-doped epitaxy process from the recesses, respectively. In some embodiments, the first and second epitaxial layers 110a and 110b are referred to as “source/drain regions”.

Thereafter, a dielectric layer 114 is formed aside the first and second dummy gate strips 106a and 106b, and formed over the first and second epitaxial layers 110a and 110b. In some embodiments, the dielectric layer 114 includes nitride such as silicon nitride, oxide such as silicon oxide, phosphosilicate glass (PSG), borosilicate glass (BSG), boron-doped phosphosilicate glass (BPSG), the like, or a combination thereof, and is formed by a suitable deposition technique such as spin-coating, CVD, flowable CVD, PECVD, ALD, the like, or a combination thereof. In some embodiments, an etch stop layer 112 is formed before the formation of the dielectric layer 114 and after the formation of the first and second epitaxial layers 110a and 110b. In some embodiments, the etch stop layer 112 includes metal oxide (e.g., Al₂O₃), SiN, SiC, SiCN, SiON, SiCON, the like, or a combination thereof. In some embodiments, an etch stop material layer and a dielectric material layer are formed over the substrate 100 covering the first and second dummy gate strips 106a and 106b, and then planarized by a suitable technique such as CMP until the top surfaces of the first and second dummy gate strips 106a and 106b are exposed. In some embodiments, the top surfaces of the dielectric layer 114 and the etching stop layer 112 are substantially level with the top surfaces of the first and second dummy gate strips 106a and 106b.

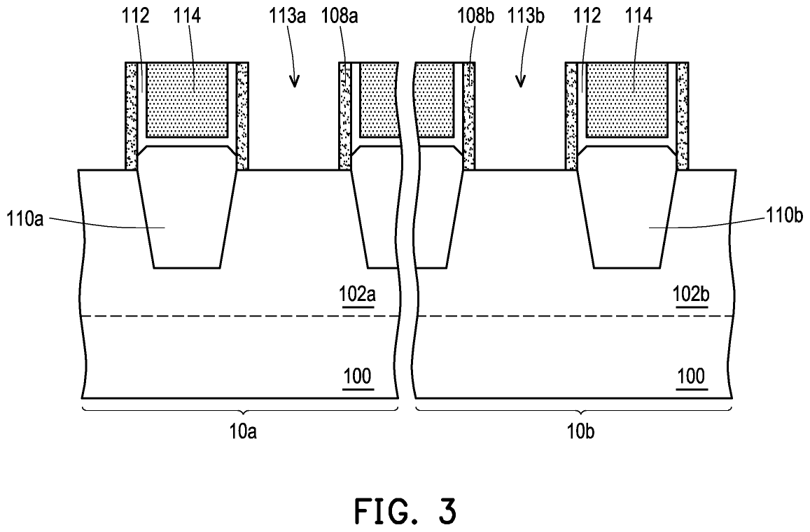

Referring to FIG. 3, the first dummy gate strip 106a is removed to form a first trench 113a in the dielectric layer 114 in the first region 10a, and the second dummy gate strip 106b is removed to form a second trench 113b in the dielectric layer 114 in the second region 10b. In some embodiments, the first and second interfacial layers 104a and 104b are simultaneously removed during the removal of the first and second dummy gate strips 106a and 106b. The removing operation includes performing a suitable etching process, such as a dry etching, a wet etching or both.

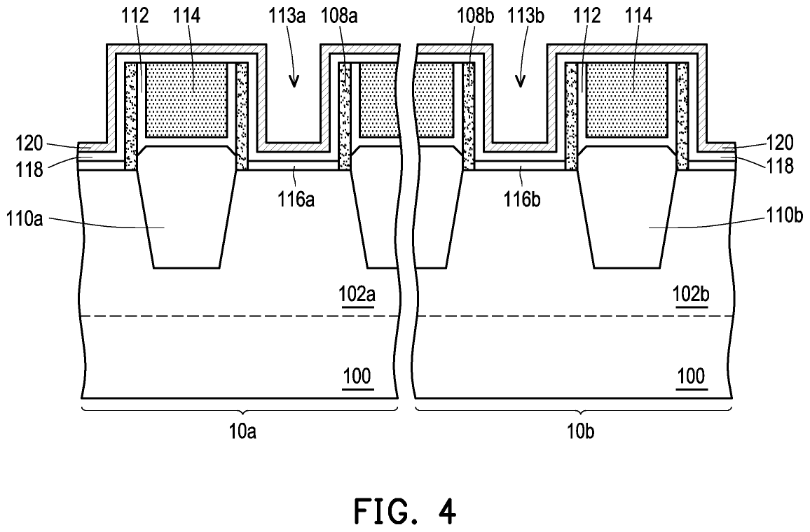

Referring to FIG. 4, a first initial layer 116a is formed on the surface of the first fin 102, and a second initial layer 116b is formed on the surface of the second fin 102b. In some embodiments, the first and second initial layer 116a and 116b have a dielectric constant less than about 8, less than about 6 or even less than about 4. In some embodiments, the first and second initial layers 116a and 116b include silicon oxide, silicon oxynitride, the like, or a combination thereof. In some embodiments, when the first and second initial layer 116a and 116b are formed by using thermal oxidation, ozone oxidation or a suitable oxidation process, the first and second initial layers 116a and 116b are formed on the bottom surfaces of the first and second trenches 113a and 113b. In other embodiments, when the first and second initial layers 116a and 116b are formed by using CVD, ALD or a suitable deposition process, the first and second initial layers 116a and 116b are formed on the entire surfaces (e.g., side and bottom surfaces) of the first and second trenches 113a and 113b.

Thereafter, the high-k material layer 118 is blanket-formed on the substrate 100 in the first and second regions 10a and 10b. In some embodiments, the high-k material layer 118 is formed over the substrate 100 and fills in the first and second trenches 113a and 113b. Specifically, the high-k material layer 118 is conformally formed on the top surface of the dielectric layer 114, on the top surfaces of the first and second initial layers 116a and 116b and on the sidewalls of the first and second trenches 113a and 113b. In some embodiments, the high-k material layer 118 has a dielectric constant greater than that of the first and second initial layer 116a and 116b. For example, the high-k material layer 118 has a dielectric constant greater than about 12, greater than about 16 or even greater than about 20. In some embodiments, the high-k material layer 118 includes metal oxide, such as ZrO₂, Gd₂O₃, HfO₂, BaTiO₃, Al₂O₃, LaO₂, TiO₂, Ta₂O₅, Y₂O₃, STO, BTO, BaZrO, HfZrO, HfLaO, HfTaO, HfTiO, a combination thereof, or a suitable material. In other embodiments, the high-k material layer 118 can optionally include a silicate such as HfSiO, HfSiON LaSiO, AlSiO, a combination thereof, or a suitable material. In some embodiments, the method of forming the high-k material layer 118 includes performing at least one suitable deposition technique, such as ALD, plasma enhance ALD (PEALD), CVD, plasma enhanced CVD (PECVD), the like, or a combination thereof.

Still referring to FIG. 4, a P-type work function metal material layer 120 is blanket-formed on the high-k material layer 118 in the first and second regions 10a and 10b. In some embodiments, the P-type work function metal material layer 120 is conformally formed over the substrate 100 along the topography of the high-k material layer 118 in the first and second regions 10a and 10b, and fills in the first and second trenches 113a and 113b. In some embodiments, the P-type work function metal material layer 120 includes TiN, WN, TaN, the like, or a combination thereof. In some embodiments, the method of forming the P-type work function metal material layer 120 includes performing at least one suitable deposition technique, such as ALD, PEALD, CVD, PECVD, the like, or a combination thereof.

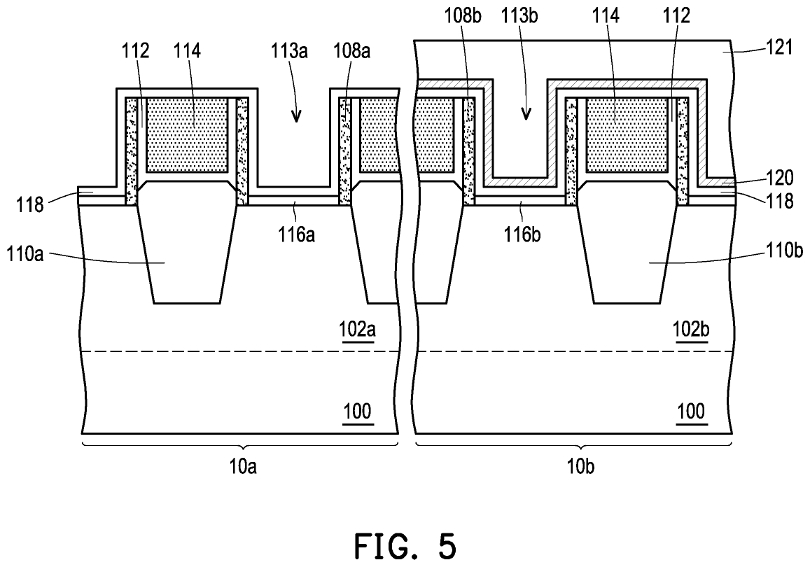

Referring to FIG. 5, the P-type work function metal material layer 120 is removed from the first region 10a. In some embodiments, a mask layer 121 is formed on the substrate 100, covers the second region 10b and exposes the first region 10a. The mask layer 121 may include a photoresist material, a dielectric material or both. Thereafter, a portion of the P-type work function metal material layer 120 is removed by using the mask layer 121 as a mask. The removing operation includes performing a suitable etching process, such as a dry etching, a wet etching or both. Upon the removing operation, the remaining P-type work function metal material layer 120 is provided in the second region 10b. In some embodiments, the P-type work function metal material layer 120 is in physical contact with the high-k material layer 118 in the second region 10b.

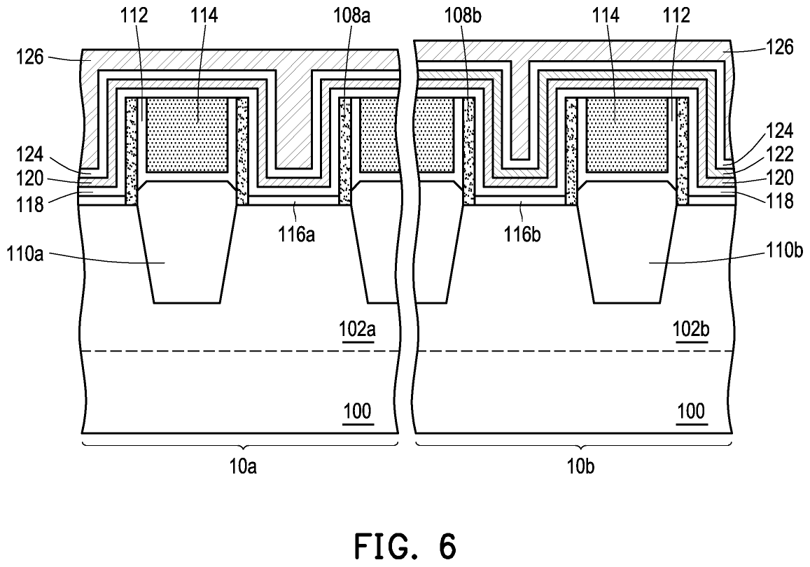

Referring to FIG. 6, an N-type work function metal material layer 122 is blanket-formed on the substrate 100 in the first and second regions 10a and 10b. In some embodiments, the N-type work function metal material layer 122 is conformally formed over the substrate 100 along the topography of the high-k material layer 118 in the first region 10a and the topography of the P-type work function metal material layer 120 in the second region 10b, and fills in the first and second trenches 113a and 113b. In some embodiments, the N-type work function metal material layer 122 includes TiAl, TiAlC, TaAl, TaAlC, the like, or a combination thereof. In some embodiments, the method of forming the N-type work function metal material layer 122 includes performing at least one suitable deposition technique, such as ALD, PEALD, CVD, PECVD, the like, or a combination thereof.

Afterwards, a barrier material layer 124 is formed on the N-type work function metal material layer 122 in the first and second regions 10a and 10b. In some embodiments, the barrier material layer 124 is conformally formed over the substrate 100 along the topography of the N-type work function metal material layer 122 in the first and second regions 10a and 10b, and fills in the first and second trenches 113a and 113b. In some embodiments, the barrier material layer 124 contains TiN, TiAlN, TaAlN, AlN or a combination thereof. In some embodiments, the barrier material layer 124 serves as a aluminum blocking layer (e.g., TiAlN, TaAlN, AlN) configured to prevent oxide from entering the underlying N-type work function metal material layer 122 and reacting with aluminum in the N-type work function metal material layer 122. In some embodiments, the barrier material layer 124 serves as an adhesion layer (e.g., TiN) configured to enhance the adhesion between the work function metal layer and subsequently formed metal filling layer. In some embodiments, the method of forming the barrier material layer 124 includes performing at least one suitable deposition technique, such as ALD, PEALD, CVD, PECVD, the like, or a combination thereof.

Upon the formation of the barrier material layer 124, a metal filling material layer 126 is formed over the substrate 100 and fills in the first and second trenches 113a and 113b. In some embodiments, the metal filling material layer 126 is configured to provide an electrical transmission. In some embodiments, the metal filling material layer 126 is formed on the barrier material layer 122 and completely fills the first and second trenches 113a and 113b. In some embodiments, the metal filling material layer 126 is formed directly on the barrier material layer 124. In some embodiments, the metal filling material layer 126 includes W, Al, Cu, the like, or a combination thereof. In some embodiments, the method of forming the metal filling material layer 126 includes performing at least one suitable deposition technique, such as ALD, PEALD, CVD, PECVD, the like, or a combination thereof.

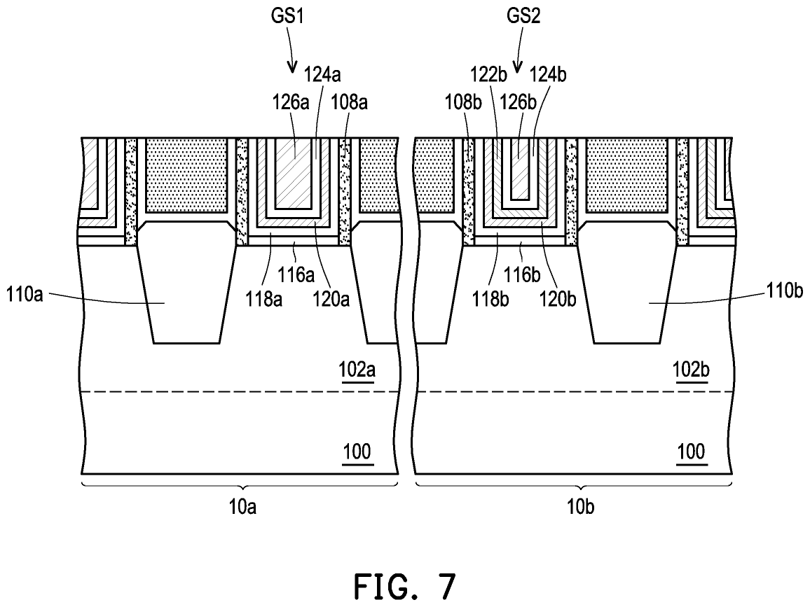

Referring to FIG. 7, excess layers outside of the first and second trenches 113a and 113b are removed, and the remaining layers form a first gate strip GS1 in the first trench 113a and a second gate strip GS2 in the second trench 113b. In some embodiments, portions of the metal filling material layer 126, the barrier material layer 124, the N-type work function metal material layer 122, the P-type work function metal material layer 120 and the high-k material layer 118 outside of the first and second trenches 113a and 113b are removed by a planarization operation such as CMP, and the remaining layers constitute the first and second gate strips GS1 and GS2 in the first and second regions 10a and 10b. The gate strips are referred to as “gate stacks” or “film stacks” in some examples.

In some embodiments, as shown in FIG. 7, the first gate strip GS1 in the first region 10a includes, from bottom to top, a first initial layer 116a, a first high-k layer 118a, a first N-type work function metal layer 122a, a first barrier layer 124a and a first metal filling layer 126a. Similarly, the second gate strip GS2 in the second region 10b includes, from bottom to top, a second initial layer 116b, a second high-k layer 118b, a P-type work function metal layer 120b, a second N-type work function metal layer 122b, a second barrier layer 124b and a second metal filling layer 126b.

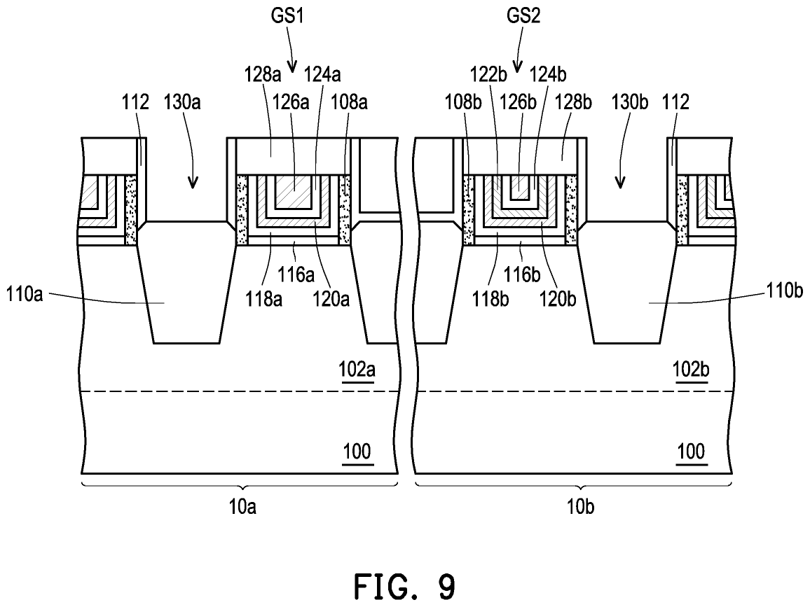

Referring to FIG. 9, upper portions of the first gate strip GS1 and the second gate strip GS2 are removed to form recesses exposing the first gate strip GS1 and the second gate strip GS2. Specifically, portions of the first gate strip GS1 and the second gate strip GS2 are removed by an etching back process, and the remaining first gate strip GS1 and the second gate strip GS2 are exposed by the recesses. In some embodiments, one of the recesses is between two adjacent first spacers 108a, and one of the recesses is between two adjacent second spacers 108b. Thereafter, first and second cap patterns 128a and 128b are formed in the recesses covering the first and second gate strips GS1 and GS2, respectively. In some embodiments, the first and second cap patterns 128a and 128b are configured to protect the first and second gate strips GS1 and GS2 from being damaged during the following contact hole defining step. In some embodiments, a cap layer is formed on the substrate 100 filling the recesses. The cap layer includes metal oxide (e.g., Al₂O₃), SiN, SiC, SiCN, SiON, SiCON, the like, or a combination thereof, and is formed by a suitable deposition technique such as CVD, plasma-enhanced CVD (PECVD), ALD, remote plasma ALD (RPALD), plasma-enhanced ALD (PEALD), the like, or a combination thereof. A CMP process is then performed to remove the cap layer outside of the recesses. In some embodiments, the first cap pattern 128a is regarded as part of the first gate strip GS1, and the second cap pattern 128b is regarded as part of the second gate strip GS2.

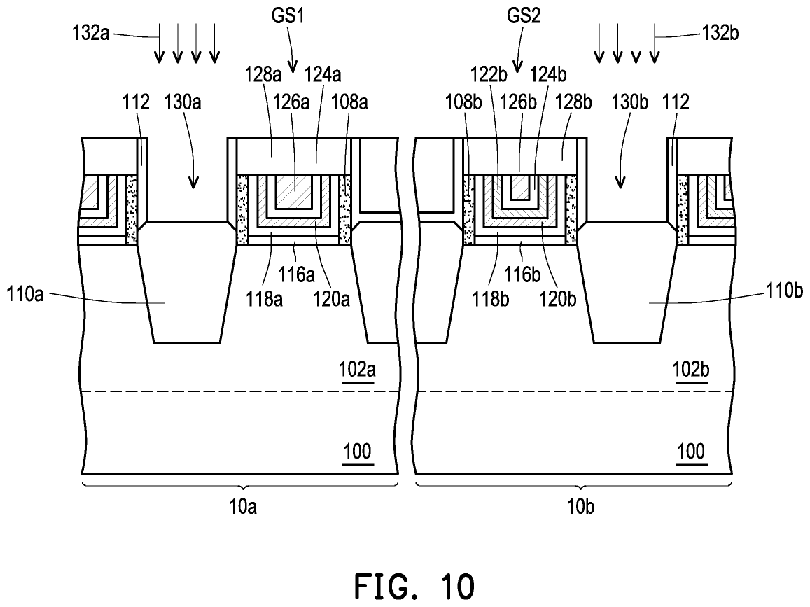

Referring to FIG. 10, the dielectric layer 114 and the etch stop layer 112 are patterned or partially removed to form first and second openings 130a and 130b (or called “contact holes”) exposing the corresponding first and second epitaxial layers 110a and 110b, respectively. In some embodiments, a mask layer such as a photoresist layer is formed on the dielectric layer 114, and an etching process is performed by using the mask layer as a mask. In some embodiments (not shown), upon the contact hole defining step, a portion of the dielectric layer 114 remains between the first opening 130a and the etch stop layer 112, and a portion of the dielectric layer 114 remains between the second opening 130b and the etch stop layer 112. In some embodiments, portions of the first and second spacers 108a and top corners of first and second cap patterns 128a and 128b are removed during the etching process, and the first and second openings 130a and 130b are formed with tilted sidewalls with wide-top and narrow-bottom profiles. In other embodiments, the first and second openings 130a and 130b can be formed with substantially vertical sidewalls. In some embodiments, the aspect ratio of the first and second openings 130a and 130b is greater than about 5 or even greater than about 10. Besides, the first and second openings 130a and 130b can be formed as plugs, pillars, strips, walls or any suitable shapes as needed.

Referring to FIG. 10, a heavily doped process 132a is performed to the exposed first epitaxial layer 110a in the first region 10a, and a heavily doped process 132b is performed to the exposed second epitaxial layer 110b in the second region 10b. In some embodiments, the heavily doped process 132a is performed by implanting an N-type dopant to the first epitaxial layer 110a to further enhance the concentration of the source/drain region for an N-type FinFET device. The N-type dopant may include P, As, Sb or the like. In some embodiments, the heavily doped process 132b is performed by implanting an P-type dopant to the second epitaxial layer 110b to further enhance the concentration of the source/drain region for a P-type FinFET device. The P-type dopant may include B, Ga or the like. The heavily doped processes 132a and 132b are performed separately. In some embodiments, a mask layer such as a photoresist layer is formed on the dielectric layer 114, covering the non-target area and exposing the target area, and a suitable dopant is implanted to the target area. In some embodiments, when the concentrations of the source/drain regions are high enough for device operation, at least one of the heavily doped processes 132a and 132b may be optional omitted as needed.

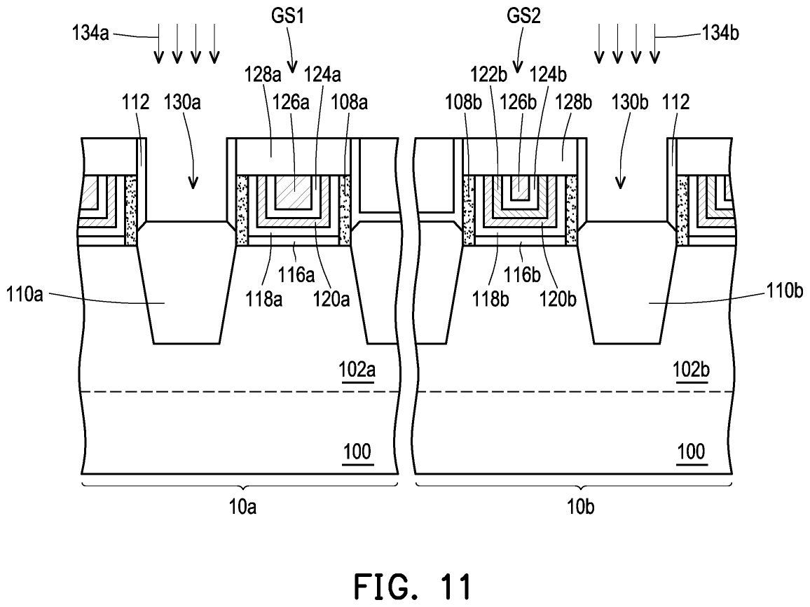

Referring to FIG. 11, a pre-amorphous implant (PAI) process 134a is performed to the exposed first epitaxial layer 110a in the first region 10a, and a pre-amorphous implant (PAI) process 134b is performed to the exposed second epitaxial layer 110b in the second region 10b. The PAI processes 134a and 134b are performed to confine siliciding formation regions in the first and second epitaxial layers 110a and 110b. The PAI process is performed to amorphize the top portions of the first and second epitaxial regions 110a and 110b. In some embodiments, the PAI processes are implemented with germanium (Ge), xenon (Xe), silicon or the like. In some embodiments, the PAI processes 134a and 134b are performed simultaneously with the same implanted species in the first and second regions 10a and 10b. In other embodiments, the PAI processes 134a and 134b are performed separately with different implanted species in the first and second regions 10a and 10b. In some embodiments, at least one of the PAI processes 134a and 134b may be optional omitted for cost reduction.

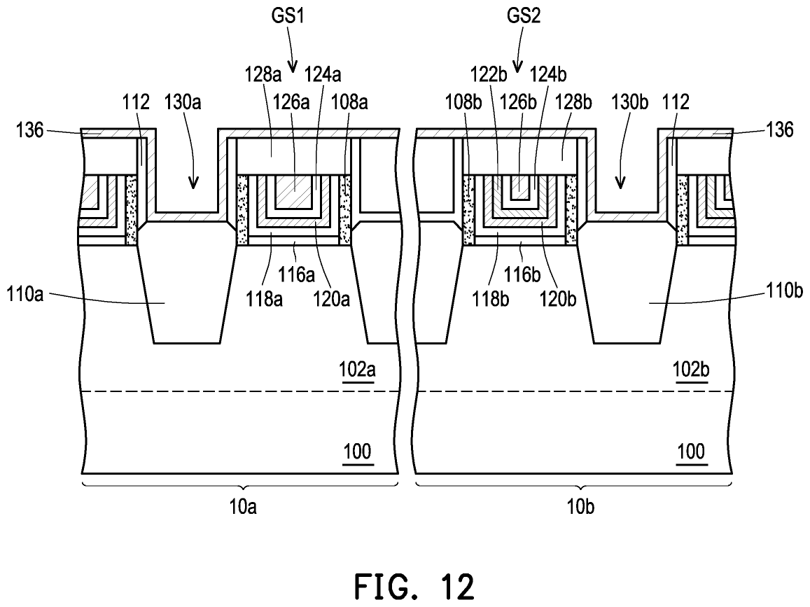

Referring to FIG. 12, a first metal layer 136 is formed on the sidewalls and bottoms of the first and second openings 130a and 130b in the first and second regions 10a and 10b. In some embodiments, a first melting point of the first metal layer 136 is about 1700° C. or higher. For example, the first melting point of the first metal layer 136 is greater than 1700° C., 2000° C., 2300° C., 2600° C. or even higher. In some embodiments, a first atomic size of the first metal layer 136 is greater than about 0.25 nm, 0.26 nm, 0.27 nm, 0.28 nm or even higher. In some embodiments, the first metal layer 136 includes Mo, V, Cr, Zr, Nb, Tc, Ru, Rh, Hf, Ta, W, Re, Os, Ir, Zr or a combination thereof. In some embodiments, the first metal layer 136 includes Mo, V, Cr, Zr, Nb, Tc, Ru, Rh, Hf, Re, Os, Ir, Zr or a combination thereof. In some embodiments, the first metal layer 136 is formed by a suitable deposition technique such as PVD, CVD, plasma-enhanced CVD (PECVD), ALD, remote plasma ALD (RPALD), plasma-enhanced ALD (PEALD), the like, or a combination thereof. In some embodiments, a pre-clean process is performed to remove residues or native oxide prior to the formation of the first metal layer 136. In some embodiments, the first metal layer 136 is a Mo layer formed by a PVD process. In some embodiments, the first metal layer 136 is formed thinner on the sidewalls of the first and second openings 130a and 130b while thicker on the bottoms of the first and second openings 130a and 130b.

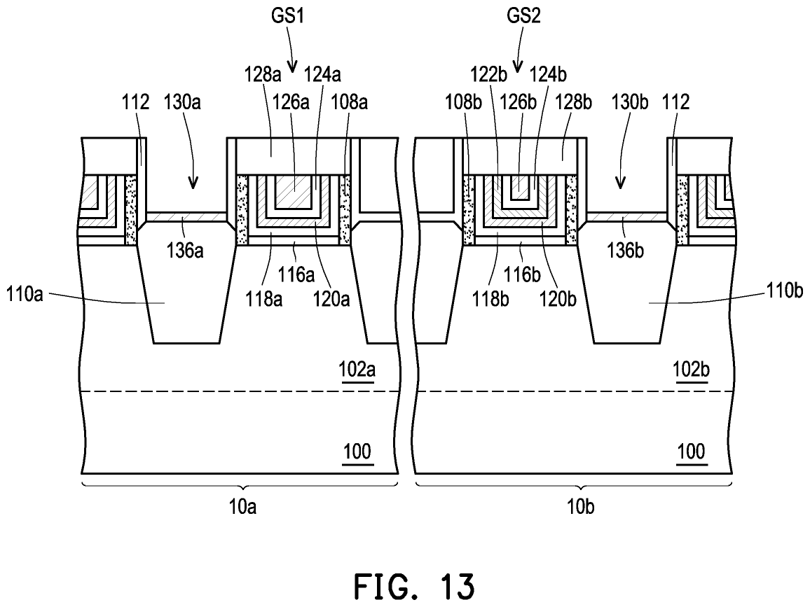

Referring to FIG. 13, the first metal layer 136 is removed from the sidewalls of the first and second openings 130a and 130b. In some embodiments, a pull-back process is performed to remove the portions of the first metal layer 136 on the sidewalls of the first and second openings 130a and 130b while remain the portions of the first metal layer 136 on the bottoms of the first and second openings 130a and 130b. The pull-back process may be a dry etching process, a wet etching process or both.

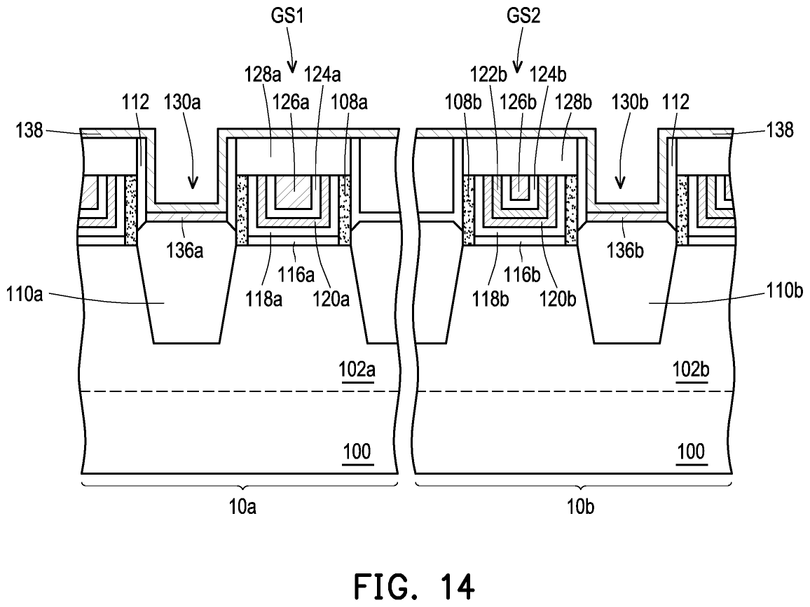

Referring to FIG. 14, a second metal layer 138 is formed on the sidewalls and the bottoms of the first and second openings 130a and 130b, and the second metal layer 138 is in contact with the first metal layer 136. In some embodiments, a second melting point of the second metal layer 138 is less than 1700° C., 1600° C., 1500° C., 1400° C., or even lower. In some embodiments, a second atomic size of the second metal layer 138 is about 0.25 nm or less. For example, the second atomic size of the second metal layer 138 is less than 0.25 nm, 0.24 nm, 0.23 nm, 0.22 nm or even less. In some embodiments, the second metal layer 138 includes Ni, Pt, Pd, Ti, Co, Sc or a combination thereof, and is formed by a suitable deposition technique such as PVD, CVD, plasma-enhanced CVD (PECVD), ALD, remote plasma ALD (RPALD), plasma-enhanced ALD (PEALD), the like, or a combination thereof. In some embodiments, the second metal layer 138 is a Ni(Pt) layer formed by an in-situ or ex-situ metal alloy deposition process.

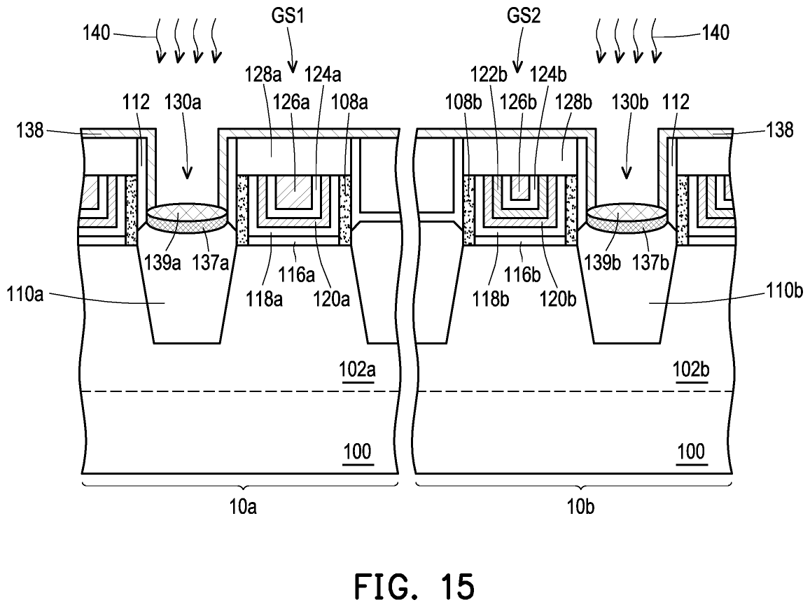

Referring to FIG. 15, a first annealing process 140 is performed to the substrate 100 in the first region 10a. In some embodiments, the first annealing process 140 is performed at a temperature of about 180-280° C. for about 10-600 seconds. The first annealing process 140 inter-mixes or silicidizes the first metal layer 136 and the second metal layer 138 on the first epitaxial layer 110a and therefore forms a bi-layer silicide structure including a lower silicide 137a and an upper silicide 139a on the first epitaxial layer 110a. The inter-mixing or silicidizing process consumes a surface portion of the first epitaxial layer 110a. In some embodiments, the lower silicide 137a is Mo-rich silicide. In some embodiments, the lower silicide 137a is MoSi without Ni/Pt or with few Ni/Pt. For example, the lower silicide 137a includes about 33-60 at % of Mo, about 45-67 at % of Si, about 0-30 at % of Ni, and about 0-10 at % of Pt. In some embodiments, the upper silicide 139a is Ni-rich silicide. In some embodiments, the upper silicide 139a is Ni(Pt)Si without Mo or with few Mo. For example, the upper silicide 139a includes about 30-45 at % of Ni, about 2-10 at % of Pt, about 30-55 at % of Si, and about 0-10 at % of Mo. In some embodiments, the lower silicide 137a has a thickness of about 0.2-3 nm, and the upper silicide 139a has a thickness of about 2-18 nm. Each of the lower silicide 137a and the upper silicide 139a may have a thinner edge thickness and a thicker center thickness. In some embodiments, each of the lower silicide 137a and the upper silicide 139a may have tapered edge portions at opposite sides.

In some embodiments, the first annealing process 140 is simultaneously performed to the substrate 100 in the second region 10b. In some embodiments, the first annealing process 140 is performed at a temperature of about 180-280° C. for about 10-600 seconds. The first annealing process 140 inter-mixes or silicidizes the first metal layer 136 and the second metal layer 138 on the second epitaxial layer 110b and therefore forms a bi-layer silicon-germanide structure including a lower silicon-germanide 137b and an upper silicon-germanide 139b on the second epitaxial layer 110b. The inter-mixing or silicidizing process consumes a surface portion of the second epitaxial layer 110b. In some embodiments, the lower silicon-germanide 137b is Mo-rich silicon-germanide. In some embodiments, the lower silicon-germanide 137b is MoSiGe without Ni/Pt or with few Ni/Pt. For example, the lower silicon-germanide 137b includes about 33-60 at % of Mo, about 22-34 at % of Si, about 22-34 at % of Ge, about 0-30 at % of Ni, and about 0-10 at % of Pt. In some embodiments, the upper silicon-germanide 139b is Ni-rich silicon-germanide. In some embodiments, the upper silicon-germanide 139b is Ni(Pt)SiGe without Mo or with few Mo. For example, the upper silicon-germanide 139b includes about 30-45 at % of Ni, about 2-10 at % of Pt, about 15-28 at % of Si, about 15-28 at % of Ge and about 0-10 at % of Mo. In some embodiments, the lower silicon-germanide 137b has a thickness of about 0.2-3 nm, and the upper silicon-germanide 139b has a thickness of about 2-18 nm. Each of the lower silicon-germanide 137b and the upper silicon-germanide 139b may have a thinner edge thickness and a thicker center thickness. In some embodiments, each of the lower silicide 137b and the upper silicide 139b may have tapered edge portions at opposite sides.

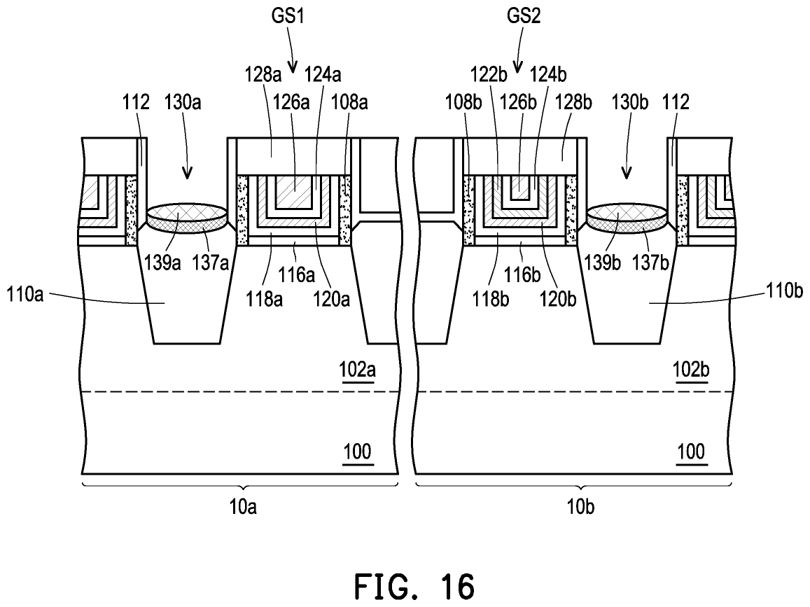

Referring to FIG. 16, the second metal layer 138 is removed from the sidewalls of the first and second openings 130a and 130b. In some embodiments, a selective process is performed to remove the second metal layer 138 on the sidewalls of the first and second openings 130a and 130b while remain the bi-layer silicide and silicon-germanide on the bottoms of the first and second epitaxial layers 110a and 110b, respectively. The selective process may be a wet etching process. For example, the wet etchant includes H₂SO₄ and H₂O₂, HCl and DIO₃, HCl and HNO₃, or the like mixing combination.

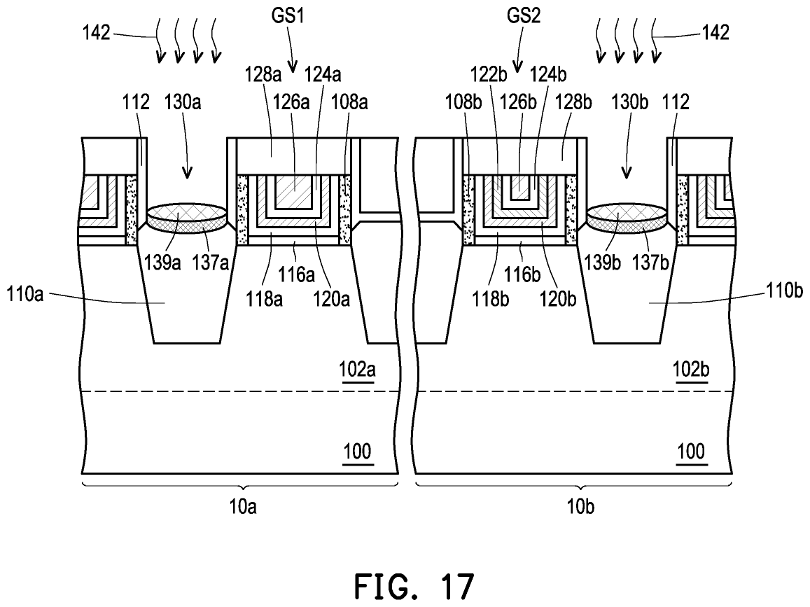

Referring to FIG. 17, a second annealing process 142 is performed to the substrate 100 in the first and second regions 10a and 10b. In some embodiments, the second annealing process 140 is performed at a temperature of about 400-480° C. for about 10-600 seconds. In some embodiments, the second annealing process 142 is configured to stabilize the structures of bi-layer silicide and silicon-germanide on the bottoms of the first and second epitaxial layers 110a and 110b. In some embodiments, the second annealing process 142 further silicidizes the bi-layer silicide and silicon-germanide into single-layer silicide and silicon-germanide on the bottoms of the first and second epitaxial layers 110a and 110b, respectively. In some embodiments, the second annealing process 142 may be omitted for cost reduction.

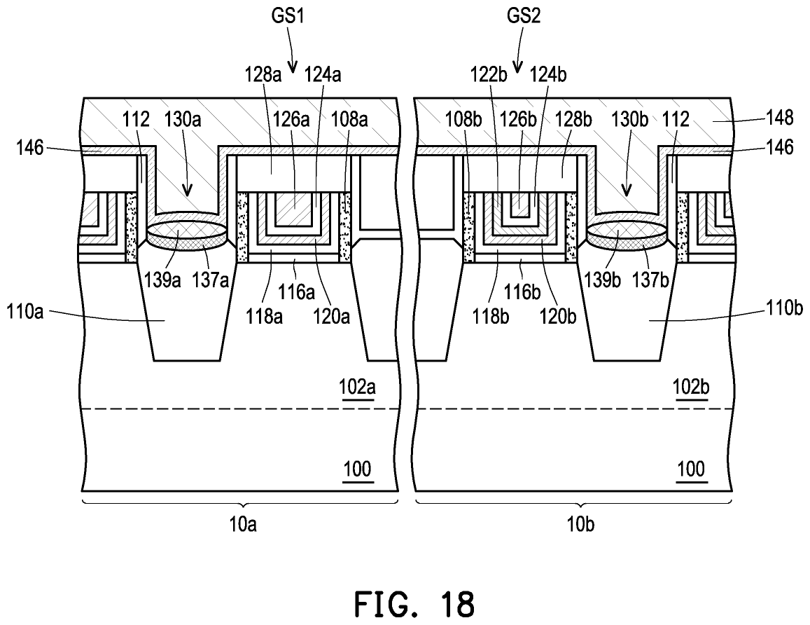

Referring to FIG. 18, a barrier layer 146 is formed on the sidewalls and bottoms of the first and second openings 130a and 130b in the first and second regions 10a and 10b, and the barrier layer 146 is in contact with the bi-layer silicide and silicon-germanide. In some embodiments, the barrier layer 136 includes Ni, Ta, TiN, TaN or a combination thereof, and is formed by a suitable deposition technique such as PVD, CVD, plasma-enhanced CVD (PECVD), ALD, remote plasma ALD (RPALD), plasma-enhanced ALD (PEALD), the like, or a combination thereof. In some embodiments, a pre-clean process is performed to remove residues or native oxide prior to the formation of the barrier layer 146.

Thereafter, a low-resistance layer 148 is formed on the barrier layer 146 and fills in the first and second openings 130a and 130b in the first and second regions 10a and 10b. In some embodiments, the low-resistance layer 148 includes W, Cu, the like, or a combination thereof, and is formed by a suitable deposition technique such as PVD, CVD, plasma-enhanced CVD (PECVD), ALD, remote plasma ALD (RPALD), plasma-enhanced ALD (PEALD), the like, or a combination thereof. In some embodiments, the barrier layer 146 may be omitted as needed, and the low-resistance layer 148 is in contact with the bi-layer silicide and silicon-germanide.

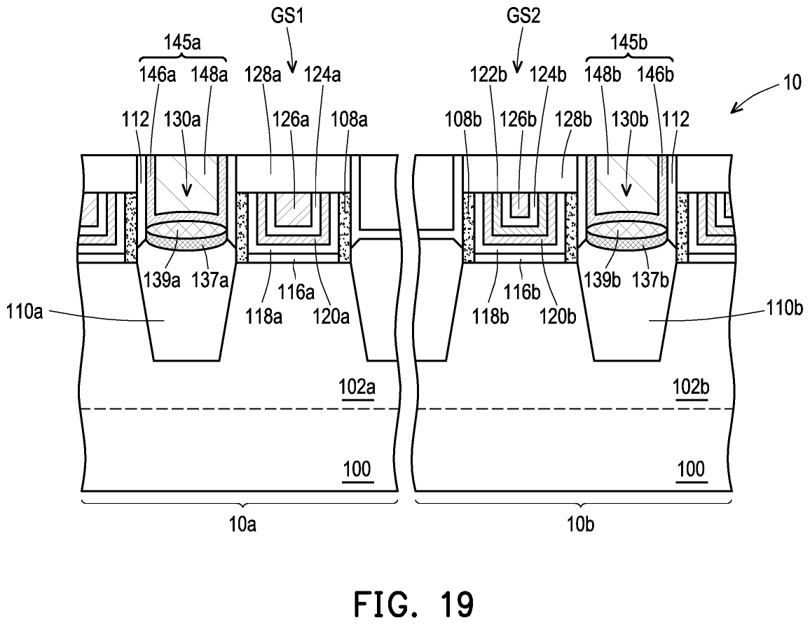

Referring to FIG. 19, the barrier layer 146 and the low-resistance layer 148 outside of the first and second openings 130a and 130b are removed, so as to form a first connector 145a including a first barrier layer 146a and a first low-resistance later 148a in the first opening 130a, and form a second connector 145b including a second barrier layer 146b and a first low-resistance later 148b in the second opening 130b. In some embodiments, the barrier layer 146 and the low-resistance layer 148 are removed by a CMP process by using the first and second cap patterns 128a and 128b as polishing stop layers. A semiconductor device 10 is thus completed.

In the disclosure, the lower portion of the silicide or silcon-germanide includes a metal with higher metaling point and greater atomic size, and such silicide or silcon-germanide provides continuous and smooth grain growth, without conventional extrusion and agglomeration profile. Accordingly, the silicide or silcon-germanide of the disclosure is beneficial to suppress Ni diffusion and spiking issue during the back end of line (BEOL) thermal process and subsequent reliability test, and therefore significantly reduce the contact resistance and improve the performance of the device.

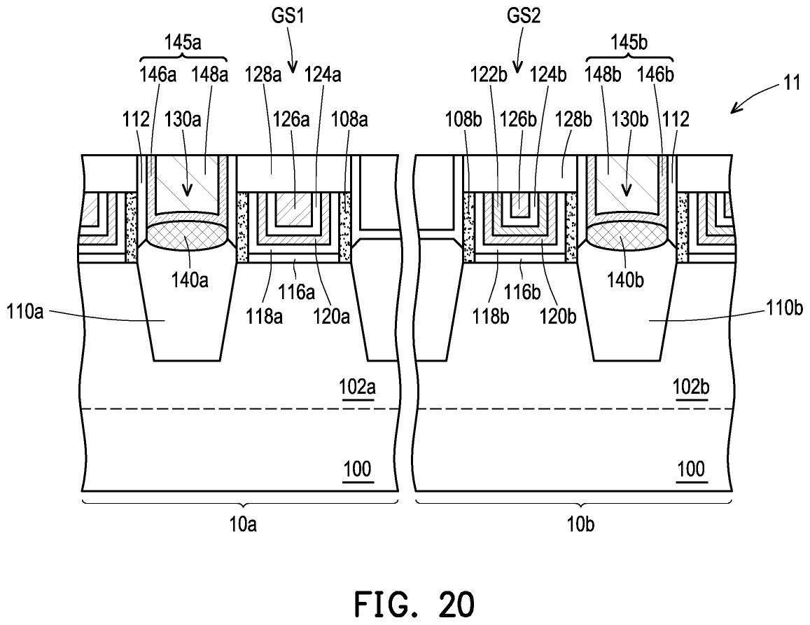

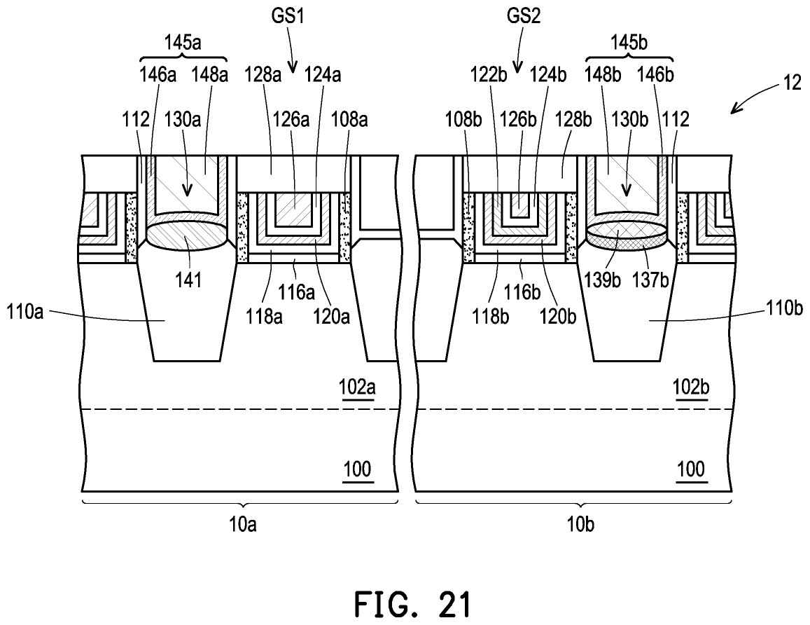

Possible modifications and alterations can be made to the above semiconductor device. These modifications and alterations are provided for illustration purposes, and are not construed as limiting the present disclosure. FIG. 20 to FIG. 21 are cross-sectional views of various semiconductor devices in accordance with other embodiments. The semiconductor devices of FIG. 20 and FIG. 21 are similar to the semiconductor device of FIG. 19, so the difference between them is illustrated in details below, and the similarity is not iterated herein.

In the semiconductor device 11 of FIG. 20, the monolayer silicide 140a replaces the bi-layer structure 137a/139a in the first region 10a (e.g., N-type device region) of the semiconductor device 10. In some embodiments, the monolayer silicide 140a is a Ni—Mo—Pt silicide or described as (Ni, Mo, Pt)Si. In some embodiments, the monolayer silicide 140a includes about 25-45 at % of Ni, about 2-10 at % of Pt, about 2-35 at % of Mo, and about 30-60 at % of Si. In some embodiments, the single-layer silicide 140a has a thickness of about 2-20 nm.

In some embodiments, the monolayer silicide 140b replaces the bi-layer structure 137b/139b in the second region 10b (e.g., P-type device region) of the semiconductor device 10. In some embodiments, the monolayer silicide 140b is a Ni—Mo—Pt silicon-germanide or described as (Ni, Mo, Pt)SiGe. In some embodiments, the monolayer silicide 140b includes about 25-45 at % of Ni, about 2-10 at % of Pt, about 2-35 at % of Mo, about 15-30 at % of Si, and about 15-30 at % of Ge. In some embodiments, the single-layer silicide 140b has a thickness of about 2-20 nm.

In the semiconductor device 12 of FIG. 21, the monolayer silicide 141 replaces the bi-layer structure 137a/139a in the first region 10a (e.g., N-type device region) of the semiconductor device 10. In some embodiments, the monolayer silicide 141 is free of Mo. In some embodiments, the monolayer silicide 141 includes nickel silicide, Ni(Pt)Si, cobalt silicide or the like.

In some embodiments, the silicon-germanide in the second region 10b (e.g., P-type device region) of the semiconductor device 12 is a bi-layer silicon-germanide the same as that of the semiconductor device 10. In other embodiments, the silicon-germanide in the second region 10b (e.g., P-type device region) of the semiconductor device 12 is a monolayer silicon-germanide the same as that of the semiconductor device 11.

In the above embodiments, the method of the disclosure is applied to a FinFET device. However, the disclosure is not limited thereto. In some embodiments, the silicide or silicon-germanide of the disclosure can be applied to a planar device upon the process requirements. Specifically, a planar substrate without fins is provided instead of the substrate 100 with fins. In other embodiments, the silicide or silicon-germanide of the disclosure can be applied to a gate-all-around (GAA) device upon the process requirements. Specifically, a substrate with nanowires is provided instead of the substrate 100 with fins.

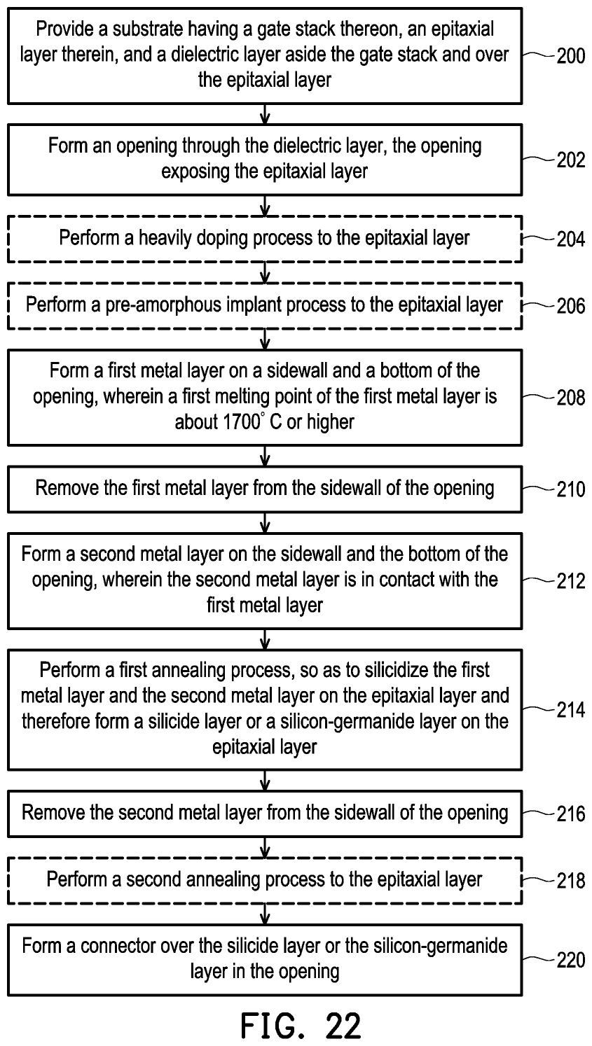

FIG. 22 illustrates a method of forming a semiconductor device in accordance with some embodiments of the present disclosure. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 200, a substrate is provided with a gate stack thereon, an epitaxial layer therein, and a dielectric layer aside the gate stack and over the epitaxial layer. FIG. 1 to FIG. 8 illustrate cross-sectional views corresponding to some embodiments of act 200. In some embodiments, forming the epitaxial layer comprises performing a heavily doping process during an epitaxial growth process.

At act 202, an opening is formed through the dielectric layer, and the opening exposes the epitaxial layer. FIG. 9 illustrates a cross-sectional view corresponding to some embodiments of act 202. In some embodiments, an etching stop layer is formed between the gate stack and the dielectric layer and between the dielectric layer and the epitaxial layer, wherein the opening further penetrates through the etching stop layer.

At act 204, a heavily doping process is performed to the epitaxial layer. FIG. 10 illustrates a cross-sectional view corresponding to some embodiments of act 204. Act 204 is optional and may be omitted as needed.

At act 206, a pre-amorphous implant process is performed to the epitaxial layer. FIG. 11 illustrates a cross-sectional view corresponding to some embodiments of act 206. Act 206 is optional and may be omitted as needed.

At act 208, a first metal layer is formed on a sidewall and a bottom of the opening, wherein a first melting point of the first metal layer is about 1700° C. or higher. FIG. 12 illustrates a cross-sectional view corresponding to some embodiments of act 208. In some embodiments, the first metal layer comprises Mo, V, Cr, Zr, Nb, Tc, Ru, Rh, Hf, Ta, W, Re, Os, Ir, Zr or a combination thereof.

At act 210, the first metal layer is removed from the sidewall of the opening. FIG. 13 illustrates a cross-sectional view corresponding to some embodiments of act 210.

At act 212, a second metal layer is formed on the sidewall and the bottom of the opening, wherein the second metal layer is in contact with the first metal layer. FIG. 14 illustrates a cross-sectional view corresponding to some embodiments of act 212. In some embodiments, a second melting point of the second metal layer is less than 1700° C. In some embodiments, the second metal layer comprises Ni, Pt, Pd, Ti, Co, Sc or a combination thereof.

At act 214, a first annealing process is performed so as to silicidize the first metal layer and the second metal layer on the epitaxial layer and therefore form a silicide layer or a silicon-germanide layer on the epitaxial layer. FIG. 15 illustrates a cross-sectional view corresponding to some embodiments of act 214. In some embodiments, the first annealing process is performed at a temperature ranging from about 180° C. to 280° C.

At act 216, the second metal layer is removed from the sidewall of the opening. FIG. 16 illustrates a cross-sectional view corresponding to some embodiments of act 216.

At act 218, a second annealing process is performed to the epitaxial layer. FIG. 17 illustrates a cross-sectional view corresponding to some embodiments of act 218. Act 218 is optional and may be omitted as needed. In some embodiments, the second annealing process to the epitaxial layer is performed at a temperature ranging from about 400° C. to 480° C. after removing the second metal layer and before forming the connector.

At act 220, a connector is formed over the silicide layer or the silicon-germanide layer in the opening. FIG. 18 to FIG. 19 illustrate cross-sectional views corresponding to some embodiments of act 220.

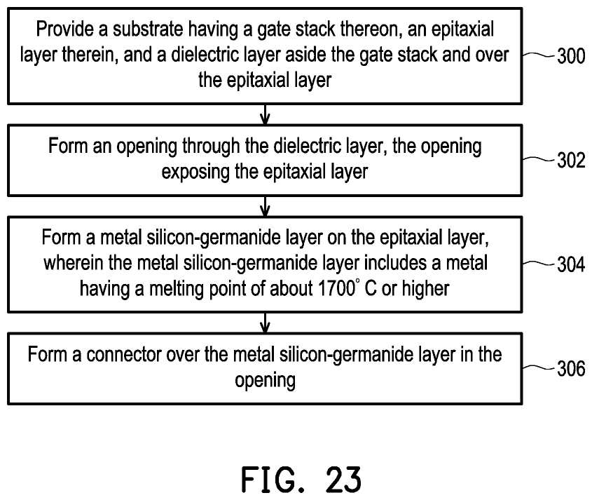

FIG. 23 illustrates a method of forming a semiconductor device in accordance with some embodiments of the present disclosure. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 300, a substrate is provided with a gate stack thereon, an epitaxial layer therein, and a dielectric layer aside the gate stack and over the epitaxial layer. FIG. 1 to FIG. 8 illustrate cross-sectional views corresponding to some embodiments of act 300.

At act 302, an opening is formed through the dielectric layer, and the opening exposes the epitaxial layer. FIG. 9 illustrates a cross-sectional view corresponding to some embodiments of act 302.

At act 304, a metal silicon-germanide layer is formed on the epitaxial layer, wherein the metal silicon-germanide layer includes a metal having a melting point of about 1700° C. or higher. FIG. 12 to FIG. 17 illustrate cross-sectional views corresponding to some embodiments of act 304. In some embodiments, the metal of the metal silicon-germanide layer has an atomic size greater than about 0.25 nm. In some embodiments, a method of forming the metal silicon-germanide layer includes forming a first metal layer in the opening, forming a second metal layer on the first metal layer in the opening, wherein a first melting point of the first metal layer is different from a second melting point of the second metal layer, and performing a first annealing process, so as to silicidize the first metal layer and the second metal layer on the epitaxial layer. In some embodiments, the first melting point of the first metal layer is about 1700° C. or higher. In some embodiments, the second melting point of the second metal layer is less than about 1700° C. In some embodiments, the first annealing process is performed at a temperature ranging from about 180° C. to 280° C. In some embodiments, metal silicon-germanide layer comprises Mo, V, Cr, Zr, Nb, Tc, Ru, Rh, Hf, Ta, W, Re, Os, Ir, Zr or a combination thereof.

At act 306, a connector is formed over the metal silicon-germanide layer in the opening. FIG. 18 to FIG. 19 illustrate cross-sectional views corresponding to some embodiments of act 306.

The structures of the semiconductor devices are described below with reference to FIG. 19 to FIG. 21.

In some embodiments, a semiconductor device 10/11/12 includes a substrate 100 having at least one fin 102b, a gate stack GS2 across the at least one fin 102b, an epitaxial layer 110b in the substrate aside the gate stack GS2, a connector 145b disposed over the epitaxial layer 110b, and a metal silicon-germanide layer 137b/139b/140b disposed between the epitaxial layer 110b and the connector 145b. In some embodiments, the metal silicon-germanide layer 137b/139b/140b includes a metal having a melting point of about 1700° C. or higher. In some embodiments, the metal has an atomic size greater than about 0.25 nm.

In some embodiments, the metal silicon-germanide layer 137b/139b/140b includes Mo, V, Cr, Zr, Nb, Tc, Ru, Rh, Hf, Ta, W, Re, Os, Ir, Zr or a combination thereof. In some embodiments, the metal silicon-germanide layer is a Mo-containing silicon-germanide layer having about 8-65 at % of Mo. In some embodiments, the thickness of the metal silicon-germanide layer 137b/139b/140b ranges from about 0.2-2.5 nm.

In some embodiments, the metal silicon-germanide layer includes a bi-layer structure including a lower Mo-rich silicon-germanide 137a and an upper Ni-rich silicon-germanide 139a. In some embodiments, the metal silicon-germanide layer 104b includes a monolayer structure.

In the disclosure, the lower portion of the silicide or silcon-germanide includes a metal with higher metaling point and greater atomic size, and such silicide or silcon-germanide provides continuous and smooth grain growth, without conventional extrusion and agglomeration profile. Accordingly, the silicide or silcon-germanide of the disclosure is beneficial to suppress Ni diffusion and spiking issue during the back end of line (BEOL) thermal process and subsequent reliability test, and therefore significantly reduce the contact resistance and improve the performance of the device.

In accordance with some embodiments of the present disclosure, a method of forming a semiconductor device includes following operations. A substrate is provided with a gate stack thereon, an epitaxial layer therein, and a dielectric layer aside the gate stack and over the epitaxial layer. An opening is formed through the dielectric layer, and the opening exposes the epitaxial layer. A metal silicon-germanide layer is formed on the epitaxial layer, wherein the metal silicon-germanide layer includes a metal having a melting point of about 1700° C. or higher. A connector is formed over the metal silicon-germanide layer in the opening.

In accordance with other embodiments of the present disclosure, a method of forming a semiconductor device includes following operations. A substrate is provided with a gate stack thereon, an epitaxial layer therein, and a dielectric layer aside the gate stack and over the epitaxial layer. An opening is formed through the dielectric layer, and the opening exposes the epitaxial layer. A first metal layer is formed on a sidewall and a bottom of the opening, wherein a first melting point of the first metal layer is about 1700° C. or higher. The first metal layer is removed from the sidewall of the opening. A second metal layer is formed on the sidewall and the bottom of the opening, wherein the second metal layer is in contact with the first metal layer. A first annealing process is performed, so as to silicidize the first metal layer and the second metal layer on the epitaxial layer and therefore form a silicide layer or a silicon-germanide layer on the epitaxial layer. The second metal layer is removed from the sidewall of the opening. A connector is formed over the silicide layer or the silicon-germanide layer in the opening.

In accordance with other embodiments of the present disclosure, a semiconductor device includes a substrate having at least one fin, a gate stack across the at least one fin, an epitaxial layer in the substrate aside the gate stack, a connector disposed over the epitaxial layer, and a metal silicon-germanide layer disposed between the epitaxial layer and the connector. In some embodiments, the metal silicon-germanide layer includes a metal having a melting point of about 1700° C. or higher.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
providing a substrate having a gate stack thereon, an epitaxial layer therein, and a dielectric layer aside the gate stack and over the epitaxial layer;
forming an opening through the dielectric layer, the opening exposing the epitaxial layer;
forming a metal silicon-germanide layer on the epitaxial layer, wherein the metal silicon-germanide layer comprises a metal having a melting point of about 1700° C. or higher; and
forming a connector over the metal silicon-germanide layer in the opening.

2. The method of claim 1, wherein the metal of the metal silicon-germanide layer has an atomic size greater than about 0.25 nm.

3. The method of claim 1, wherein a method of forming the metal silicon-germanide layer comprises:
forming a first metal layer in the opening;
forming a second metal layer on the first metal layer in the opening, wherein a first melting point of the first metal layer is different from a second melting point of the second metal layer; and
performing a first annealing process, so as to silicidize the first metal layer and the second metal layer on the epitaxial layer.

4. The method of claim 3, wherein the first melting point of the first metal layer is about 1700° C. or higher.

5. The method of claim 3, wherein the second melting point of the second metal layer is less than about 1700° C.

6. The method of claim 3, wherein the first annealing process is performed at a temperature ranging from about 180° C. to 280° C.

7. The method of claim 1, wherein metal silicon-germanide layer comprises Mo, V, Cr, Zr, Nb, Tc, Ru, Rh, Hf, Ta, W, Re, Os, Ir, Zr or a combination thereof.

8. A method of forming a semiconductor device, comprising:
providing a substrate having a gate stack thereon, an epitaxial layer therein, and a dielectric layer aside the gate stack and over the epitaxial layer;
forming an opening through the dielectric layer, the opening exposing the epitaxial layer;
forming a first metal layer on a sidewall and a bottom of the opening, wherein a first melting point of the first metal layer is about 1700° C. or higher;
removing the first metal layer from the sidewall of the opening;
forming a second metal layer on the sidewall and the bottom of the opening, wherein the second metal layer is in contact with the first metal layer;
performing a first annealing process, so as to silicidize the first metal layer and the second metal layer on the epitaxial layer and therefore form a silicide layer or a silicon-germanide layer on the epitaxial layer;
removing the second metal layer from the sidewall of the opening; and
forming a connector over the silicide layer or the silicon-germanide layer in the opening.

9. The method of claim 8, wherein the first metal layer comprises Mo, V, Cr, Zr, Nb, Tc, Ru, Rh, Hf, Ta, W, Re, Os, Ir, Zr or a combination thereof.

10. The method of claim 8, wherein a second melting point of the second metal layer is less than 1700° C.

11. The method of claim 8, wherein the second metal layer comprises Ni, Pt, Pd, Ti, Co, Sc or a combination thereof.

12. The method of claim 8, wherein the first annealing process is performed at a temperature ranging from about 180° C. to 280° C.

13. The method of claim 8, wherein forming the epitaxial layer comprises performing a heavily doping process during an epitaxial growth process.

14. The method of claim 8, further comprising, after forming the opening and before forming the first metal layer, performing a heavily doping process to the epitaxial layer.

15. The method of claim 8, further comprising, after forming the opening and before forming the first metal layer, performing a pre-amorphous implant process to the epitaxial layer.

16. The method of claim 8, further comprising forming an etching stop layer between the gate stack and the dielectric layer and between the dielectric layer and the epitaxial layer, wherein the opening further penetrates through the etching stop layer.

17. The method of claim 8, further comprising performing a second annealing process to the epitaxial layer at a temperature ranging from about 400° C. to 480° C. after removing the second metal layer and before forming the connector.

18. A semiconductor device, comprising:
a substrate having at least one fin;
a gate stack across the at least one fin;
an epitaxial layer in the substrate aside the gate stack;
a connector disposed over the epitaxial layer; and
a metal silicon-germanide layer disposed between the epitaxial layer and the connector, wherein the metal silicon-germanide layer comprises a metal having a melting point of about 1700° C. or higher.

19. The semiconductor device of claim 18, wherein the metal silicon-germanide layer comprises Mo, V, Cr, Zr, Nb, Tc, Ru, Rh, Hf, Ta, W, Re, Os, Ir, Zr or a combination thereof.

20. The semiconductor device of claim 18, wherein the metal silicon-germanide layer comprises a bi-layer structure including a lower Mo-rich silicon-germanide and an upper Ni-rich silicon-germanide.
